(19) United States
(12) Patent Application Publication
(10) Pub. No.: US 2024/0113217 A1
(43) Pub. Date: Apr. 4, 2024

(54) TRENCH SHIELDED TRANSISTOR

(71) Applicant: Texas Instruments Incorporated, Dallas, TX (US)

(72) Inventors: Hong Yang, Wylie, TX (US); Thomas Grebs, Bethlehem, PA (US); Yunlong Liu, Chengdu (CN); Sunglyong Kim, Allen, TX (US); Lindong Li, Chengdu (SC); Peng Li, Chongqing (CN); Seetharaman Sridhar, Richardson, TX (US); Yeguang Zhang, Chengdu (SC); Sheng pin Yang, Chengdu (SC)

(21) Appl. No.: 17/958,205

(22) Filed: Sep. 30, 2022

(51) Int. Cl. H01L 29/78; H01L 21/8234; H01L 27/092; H01L 29/423

(52) U.S. Cl. CPC H01L 29/7813; H01L 21/823437; H01L 27/092; H01L 29/42368

(57) ABSTRACT

An integrated circuit includes first and second trenches in a semiconductor substrate and a semiconductor mesa between the first and second trenches. A source region having a first conductivity type and a body region having an opposite second conductivity type are located within the semiconductor mesa. A trench shield is located within the first trench, and a gate electrode is over the trench shield between first and second sidewalls of the first trench. A gate dielectric is on a sidewall of the first trench between the gate electrode and the body region, and a pre-metal dielectric (PMD) layer is over the gate electrode. A gate contact through the PMD layer touches the gate electrode between the first and second sidewalls, and a trench shield contact through the PMD layer touches the trench shield between the first and second sidewalls.

### BACKGROUND

Described examples relate to semiconductor fabrication and devices, for example with respect to a trench-shielded field effect transistor (FET).

Some semiconductor devices include a transistor with a trench, and a gate within the trench that controls transistor current flow generally along the walls of the trench. Because the trench, and the current flow, are generally from a top surface of the semiconductor bulk (or stack) relative to a bottom surface, the transistor is sometimes referred to as a vertical transistor, for example as compared to other types of transistors, such as planar transistors, in which current flow is generally parallel to an outer surface of the semiconductor bulk. The vertical transistor may provide more favorable attributes, for example for certain implementations including low to mid-voltage power devices, in which low leakage is desired when the transistor is off, and in which low resistance, and high and efficient power transfer, are desired when the transistor is on. A vertical transistor also may include a shield, for example, polycrystalline silicon (sometimes referred to as polysilicon) within the trench, also to improve electrical field non-uniformities along the trench. Efficiently forming these structures, for example with an acceptable number of fabrication steps and in view of photolithography limitations, can present production difficulties.

### SUMMARY

Various examples provide an integrated circuit that includes first and second trenches in a semiconductor substrate and a semiconductor mesa between the first and second trenches. A source region having a first conductivity type and a body region having an opposite second conductivity type are located within the semiconductor mesa. A trench shield is located within the first trench, and a gate electrode is over the trench shield between first and second sidewalls of the first trench. A gate dielectric is on a sidewall of the first trench between the gate electrode and the body region, and a pre-metal dielectric (PMD) layer is over the gate electrode. A gate contact through the PMD layer touches the gate electrode between the first and second sidewalls, and a trench shield contact through the PMD layer touches the trench shield between the first and second sidewalls.

Other examples provide a method of forming an integrated circuit. The method includes forming a trench in a semiconductor substrate, the trench having first and second trench sidewalls. A first dielectric layer is formed along the first and second trench sidewalls, and a polysilicon element is formed between the first and second trench sidewalls. A portion of the polysilicon element is removed along a portion of the trench thereby forming a trench shield. A gate conductor is formed within the trench portion and spaced apart from the trench shield by a lateral insulator. A trench shield contact is formed that lands on the trench shield and a gate contact is formed that lands on the gate conductor, the trench shield contact and gate contact extending through a pre-metal dielectric layer over the trench.

Other aspects are also described and claimed.

### BRIEF DESCRIPTION OF THE DRAWINGS

FIG. 1 is a plan and partial view of the trench-shielded FET.

FIG. 2 illustrates a cross-section of a portion of a first end from FIG. 1.

FIG. 3A illustrates a cross-section of a portion of a second end from FIG. 1.

FIG. 3B illustrates a cross-section of a trench between the first end from FIG. 1 and the second end from FIG. 1.

FIG. 4 illustrates a cross-section of a portion between the first end of FIG. 2 and the second end from FIG. 3A.

FIG. 5 illustrates a cross-section in the x-dimension of FIG. in an earlier stage of fabrication.

FIG. 6 illustrates a cross-section of a successive fabrication stage applicable to structures shown above in FIGS. 2 through 4.

FIGS. 7 through 12 illustrate successive stages of fabrication following FIG. 6.

FIG. 13 illustrates the FIG. 12 cross-section after additional fabrication steps, and it also may apply to any one or more of the structures shown in FIG. 2.

FIG. 14 illustrates the FIG. 6 cross-section after additional fabrication steps and toward the completion of the structures shown above in FIG. 3.

FIG. 15 illustrates the FIG. 12 cross-section after additional fabrication steps, but in a different location along the FIG. 1 y-dimension, to demonstrate the completion of the structures shown above in FIG. 4.

FIG. 16 is a method, in flow chart form, that summarizes certain fabrication steps in forming the trench-shielded FET.

### DETAILED DESCRIPTION

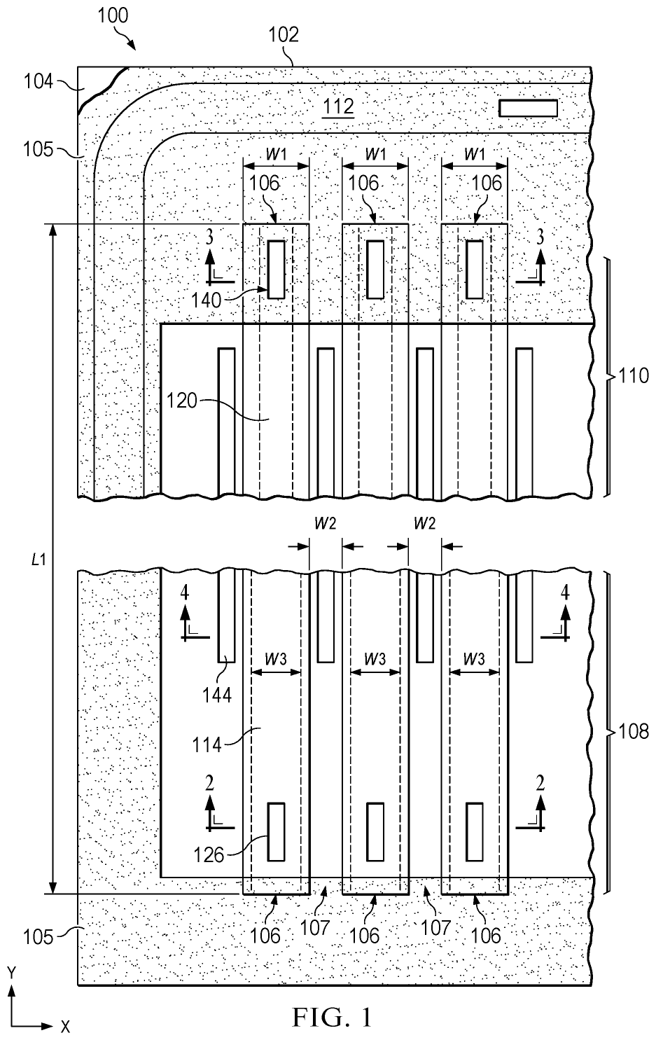

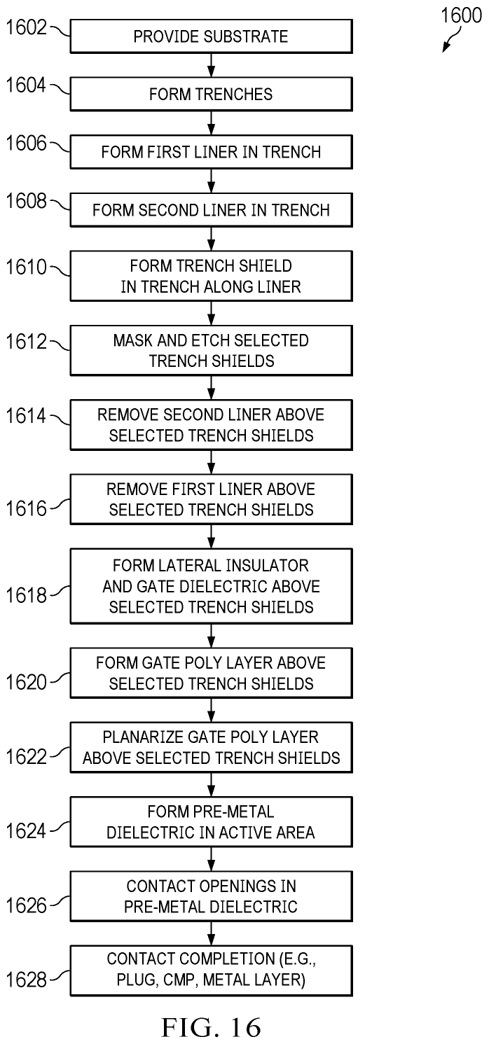

Various examples are described with reference to views FIGS. 1 through 14, representing successive fabrication stages and resultant structures of an example semiconductor device, including portions of a trench-shielded FET 100, and FIG. 16 is a method 1600, in flow chart form, that summarizes steps of those fabrication stages. The figures are not drawn to scale, are provided for illustration, and in some instances are simplified for context, while numerous specific details, relationships, and methods are set forth to provide an understanding of various examples. The present disclosure is not limited by the illustrated ordering of acts or events, as some acts may occur in different orders and/or concurrently with other acts or events. Further, not all illustrated acts or events are required to implement a methodology or construct a device in accordance with the present teachings.

Various disclosed methods and devices of the present disclosure may be beneficially applied to, for example, trench-gate MOSFET transistors. While such embodiments may be expected to provide improvements in processing such that photolithography and/or etch processing margins are increased, no particular result is a requirement unless explicitly recited in a particular claim.

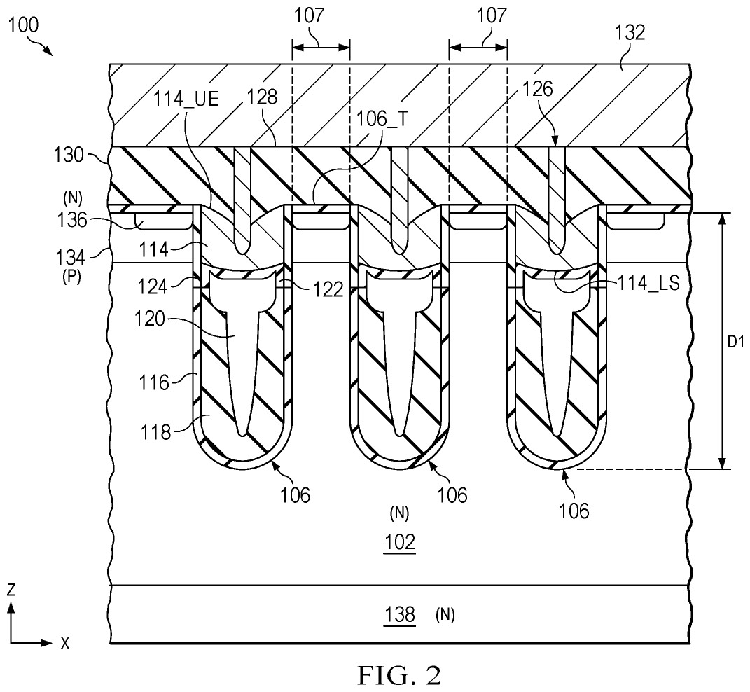

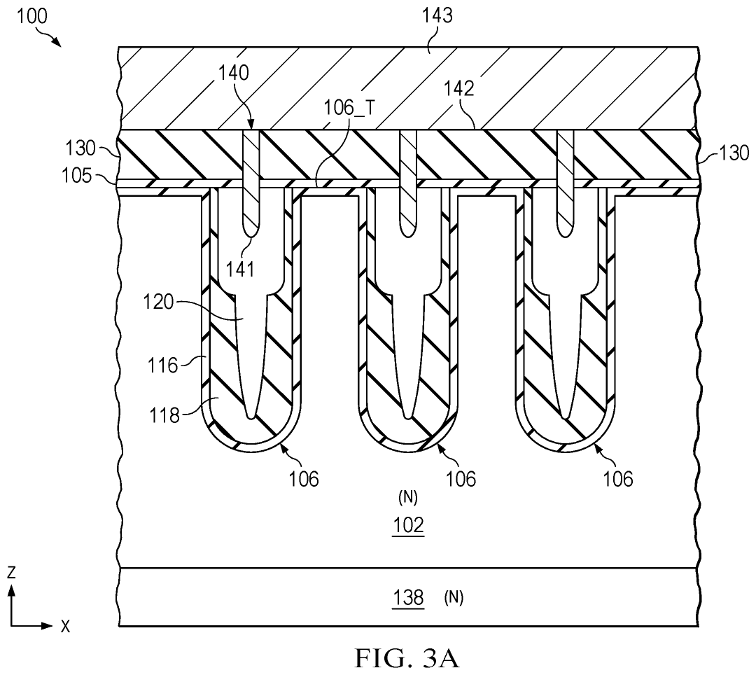

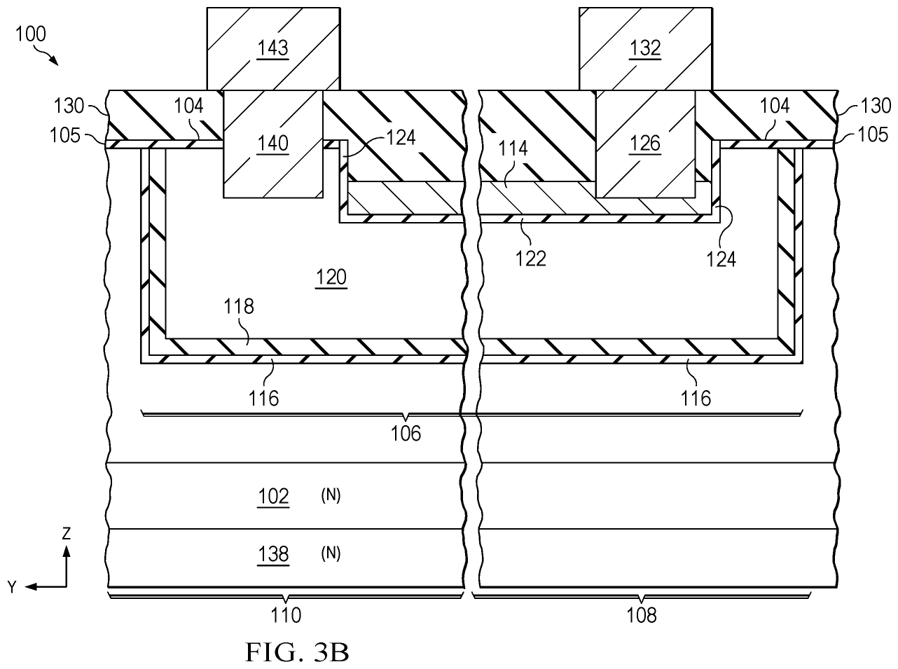

FIG. 1 is a plan and partial view of the trench-shielded FET 100, which may be formed as part of, or as a standalone, integrated circuit (IC). The FIG. 1 plan view shows two dimensions (indicated as the x- and y-dimensions) relative to, and for example above, a substrate 102, and with the z-dimension out of the page and shown in FIGS. 2 through 14. The substrate 102 includes a semiconductor material, such as silicon, and for example may be formed of, or to include, n-type doped material. The substrate 102 includes a first (e.g., top) surface 104. Around the outer perimeter of the surface 104, and extending inward to a certain extent, is an insulating border, typically formed and referred to as a field oxide 105, which may be formed by any suitable method, e.g. a chemical vapor deposition (CVD) process using tetraethyl orthosilicate (TEOS) (Si(OC2H5)₄), the resulting oxide film sometimes referred to PETEOS. The area within the boundaries of, that is, not covered by, the field oxide 105, is sometimes referred to as the active region or active area. A plurality of generally parallel trenches 106 are formed within the surface 104. As examples, in total, there may be in a range of hundreds to thousands of trenches 106, with each trench 106 having a length L1 between 10 μm and 10 mm, a width W1 of 0.5 μm to 2.0 μm, and a depth D1 (not visible in the FIG. 1 perspective, but see for example FIG. 2) from 3 μm to 10 μm, with a ratio of depth to width, referred to as an aspect ratio, of 3:1 to 10:1. An inter-trench area 107, sometimes referred to as a mesa 107, exists between each pair of adjacent trenches 106, and has a width W2 of 0.6 μm to 3 μm. Each of the trenches 106 generally includes a first end 108 and a second 110. FIG. 2 illustrates a cross-section of a portion of the first end 108, and FIG. 3 illustrates a cross-section of a portion of the second end 110. A termination trench 112, having comparable width and depth to each of the trenches 106, also may be formed outward from the generally parallel trenches 106, for example around a portion (or entirety) near the outer perimeter of the first surface 104.

FIG. 2 illustrates a cross-section of a portion of the FIG. 1 first end 108 including structure within the trenches 106, and note that the FIG. 2 cross-section positioning is beyond the FIG. 1 field oxide 105. Since FIG. 1 illustrates three trenches 106 as a partial illustration, then FIG. 2 likewise illustrates those three trenches 106. With respect to each trench 106, a gate conductor 114 has an upper edge 114_UE that terminates at a point in the z-dimension that may align generally with, or from processing be slightly recessed from, a top 106_T of the trench 106. The gate conductor 114 also includes a lower surface 114_LS within the trench 106. The gate conductor 114 may be formed from polysilicon, and from a formation process that may cause it to bow toward its middle, while formed from a layer having a thickness in the range of 300 nm to 1 μm. The gate conductor 114 has a width W3 (see FIG. 1), which is slightly less than the width W1 of the trench 106. Within the trench 106 there are four different insulators: (i) a first liner 116 adjacent the trench vertical and bottom walls; (ii) a second liner 118 that is adjacent a portion of the first liner 116, and that also abuts a portion of a trench shield 120; (iii) a lateral insulator 122 above a top of the trench shield 120 and below the lower surface 114_LS of the gate conductor 114; and (iv) a gate dielectric 124 between respective sidewalls of the gate conductor 114 and an upper portion of the vertical wall of the trench 106. Detailed later, the trench shield 120 is a conductor, for example polysilicon, that fills a portion of the trench 106 within a central portion of the second liner 118. A gate contact 126 is formed above each trench 106, and such that one axis (a central axis) extends primarily in the z-dimension from a layer interface 128, from which the gate contact passes through a pre-metal dielectric (PMD) layer 130, which may include one or more dielectric layers, and contacts an upper surface of the gate conductor 114. The layer interface 128 can represent a surface, such as a plane, between the PMD layer 130 and a gate interconnection bus 132 over or on the PMD layer 130. The gate interconnection bus 132 may be formed from any suitable metal layer, for example aluminum.

The FIG. 2 cross-section of a portion of the first end 108 also illustrates structures between or otherwise outside of the trenches 106. A body layer 134 is positioned in the FIG. 1 mesa 107, that is, between tops 106_T of adjacent trenches 106. The body layer 134 is of semiconductor material that is complementary to the bulk material of the substrate 102. Accordingly, in the example where the substrate 102 is n-type, then the body layer 134 is p-type. Further, a source region 136 is also positioned adjacent the trench 106 in the FIG. 1 mesa 107, and closer to the first surface 104 (see FIG. 1) than, or within the upper portion of, the body layer 134. Each source region 136 is of complementary conductivity type to the body layer 134. Accordingly, in the example where the body layer 134 is p-type, then each source region 136 is n-type. A drain contact region 138 is aligned along the bottom of the substrate 102, and for example the drain contact region 138 includes a higher concentration n-type doping as compared to the of the substrate 102. From the preceding and in general, an electrical signal to the gate conductor 114 can induce an n-type channel (not shown) in the body layer 134, generally in the z-dimension, and between the source region 136 and the substrate 102 (acting as a drain extension), so that current passes between those regions and to the drain contact region 138. The current path may be considered a vertical dimension in the nominal layout of the trench-shielded FET 100, in which case the trench-shielded FET 100 may be referred to as a vertical FET. Further, a bias (e.g., ground) applied to the trench shield 120 can produce a desirable electric field distribution of the transistor current path.

FIG. 3A illustrates a cross-section of a portion of the FIG. 1 second end 110, including structure within the trenches 106 and again illustrating the three FIG. 1 trenches 106. The FIG. 3A cross-section positioning also includes the FIG. 1 field oxide 105, which for example may have a thickness of 0.15 μm to 0.50 μm. In general, the second end 110 includes structures configured to provide electrical contact to each trench shield 120. (See also FIG. 3B.) Accordingly, certain FIG. 3A structure may resemble that of FIG. 2, while other aspects may be eliminated if not needed (or desired) in the area of such contact. For example, within each trench 106, again there are a first liner 116 adjacent the trench vertical and bottom walls and a second liner 118 that is adjacent a portion of the first liner 116, where the second liner 118 also abuts a portion of the trench shield 120. However, in contrast to the structure of the first end 108 illustrated in FIG. 2, in FIG. 3A, and for the area near the second end 110, the uppermost surface (in the z-dimension) of each trench shield 120 extends near or to the top 106_T of the trench 106. Further, the second end 110 does not include the FIG. 2 gate conductor 114, the gate dielectric 124, or the lateral insulator 122 above a top of the trench shield 120. Additional structure related to the vertical FET functionality also may be eliminated in the second end 110, for example including either or both of the FIG. 2 body layer 134 and the source region 136. Also in FIG. 3A, the FIG. 1 field oxide 105 is located over each trench shield 120. A trench shield contact 140 is formed above each trench 106 and such that its vertical axis extends primarily in the z-dimension from a layer interface 142, and the trench shield contact 140 has a contact tip 141 and is aligned so that the contact tip 141 contacts an upper surface of the trench shield 120 between or within the walls of the trench 106. In an example, the trench shield contact 140 passes through a dielectric layering, which can be the same PMD layer 130 from FIG. 2, in addition to the field oxide 105. The layer interface 142 can represent a surface, such as a plane, between the PMD layer 130 and a source/shield interconnection bus 143 on or over the PMD layer 130. The source/shield interconnection bus 143 may be formed from any suitable metal layer, for example aluminum The gate interconnection bus 132 and source/shield interconnection bus 143 may formed from the same metal layer(s), and may thus have top surfaces that are coplanar.

FIG. 3B illustrates a cross-section in the y-z plane of FIG. 1 of one trench shield 120 between the first end 108 and the second end 110. One instance each of the gate contact 126 and the trench shield contact 140 are present in this view. The gate contact 126 extends between the gate interconnection bus 132 and the gate conductor 114, and forms an ohmic connection to the gate conductor 114. The trench shield contact 140 extends between the source/shield interconnection bus 143 and the trench shield 120, and forms an ohmic connection to the trench shield 120. The gate dielectric 124 between the gate conductor 114 and vertical sidewalls of the trench shield 120 isolate the gate conductor 114 from the trench shield 120 such that the gate conductor 114 and the trench shield 120 may respectively be separately biased by the gate interconnection bus 132 and the source/shield interconnection bus 143. Notably, the gate contact 126 is at a same level in the z-direction as the trench shield contact 140, and the gate interconnection bus 132 is at a same level in the z-direction as the source/shield interconnection bus 143. This planar arrangement is in contrast with some baseline transistors that use a polysilicon bus over the field oxide 105 to provide a common electrical node connected to the trench shields 120. Such baseline devices present a significant topography, or difference of levels of material surfaces, which may result in a small depth of focus (DOF) when exposing a resist level used for material patterning. The planar arrangement reduces such topography and increases the DOF, as further described below.

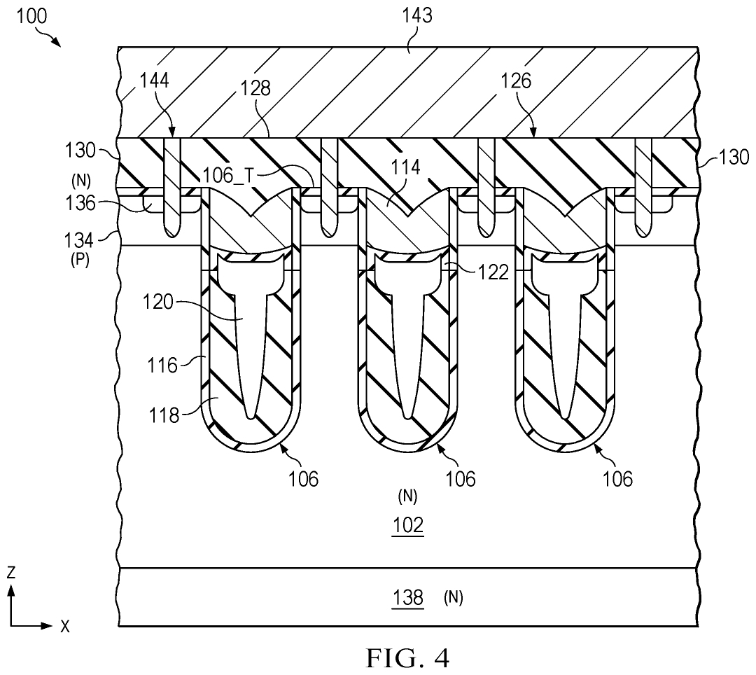

FIG. 4 illustrates a cross-section of another portion of the first end 108, with the illustrated structure including source contacts 144 outside of the trenches 106 (laterally away from the trenches 106 in the x-dimension) and extending primarily in the z-dimension from the layer interface 128. In general, each source contact 144 makes an ohmic connection to a respective source region 136. The source contact 144 also may extend through the respective source region 136 and into a respective portion of the body layer 134. In an example, each source contact 144 passes through a dielectric layering, which can be the same PMD layer 130 from FIG. 2 (and FIG. 3A), which may include one or more dielectric layers. The layer interface 128 may represent a lower surface of the source/shield interconnection bus 143, in which case each source contact 144 is electrically coupled also to the FIG. 3A trench shield contacts 140.

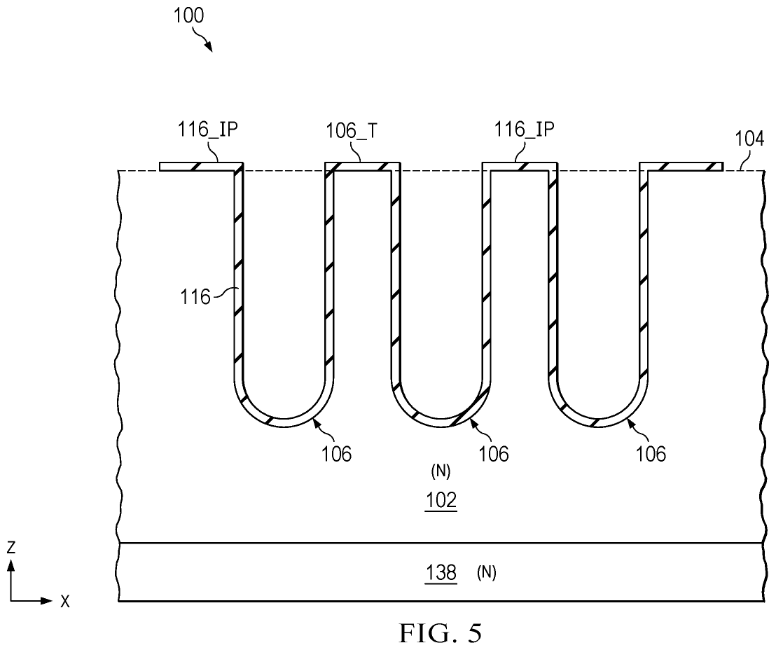

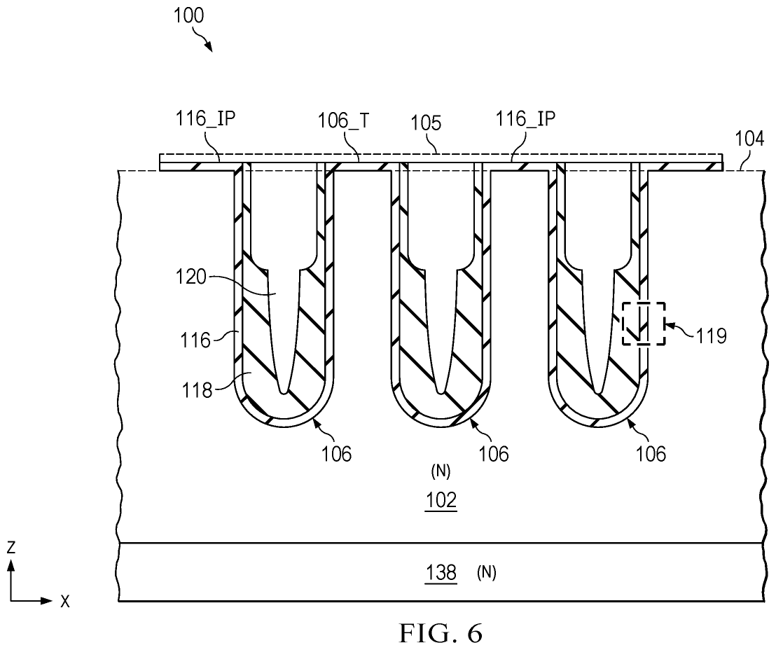

FIG. 5 illustrates a cross-section in the x-dimension of FIG. 1 across the three trenches 106, in an earlier stage of fabrication, as the following description of this and subsequent Figures provides additional detail to certain example aspects. As demonstrated below, the earlier fabrication stage of FIG. 5 may apply to any one or more of the structures shown above in FIGS. 2 through 4. Further, the following description of FIG. 5, and of successive FIGS. 6 through 15, illustrate fabrication steps also summarized in a fabrication method 1600, shown in FIG. 16.

In FIG. 5, the substrate 102 is provided (FIG. 16, 1602), and an area of the substrate 102 is provided for the trench-shielded FET 100. Each of the trenches 106 is formed (FIG. 16, 1604) from the top surface 104 of the substrate 102, extending in the z-dimension into the substrate 102 and away from the top surface 104, thereby defining the top 106_T of the trench 106 aligned with the top surface 104. The first liner 116 is formed (FIG. 16, 1606) at least along the walls (vertical (z-dimension) and bottom) of the trenches 106, and it also may extend along the remaining portions (x-dimension) of the top surface 104 between the trenches 106, thereby providing first liner insulating portions 116_IP. The first liner 116 may be formed by a thermal oxidation process, for example at a temperature above 800° C. and thereby including primarily thermal silicon dioxide having a stoichiometric composition of silicon dioxide, that is, SiO2, and a hydrogen content less than 5 atomic percent. The first liner 116 may have a thickness of 20 nm (nanometers) to 200 nm in the trenches 106.

FIG. 6 illustrates the FIG. 5 cross-section after additional fabrication steps, and it also may apply to any one or more of the structures shown above in FIGS. 2 through 4. A layer is formed (FIG. 16, 1608) over the FIG. 5 structure to fill the trenches 106 and is then reduced (e.g., etched) to form the second liner 118. The second liner 118 may be formed by a PETEOS process. The thermal CVD process may be implemented as a sub-atmospheric chemical vapor deposition (SACVD) process, for example, or as an atmospheric pressure chemical vapor deposition (APCVD) process. Alternatively, the second liner 118 may be formed by a plasma enhanced chemical vapor deposition (PECVD) process, using TEOS. The second liner 118 may include primarily silicon dioxide, and may be formed below 600° C. The second liner 118 may be formed to have a greater thickness proximate to bottoms of the trenches 106 than proximate to the tops 106_T of the trenches 106. The second liner 118 may be formed in two or more steps to attain a desired thickness profile in the trenches 106. The second liner 118 may be removed from over the top 106_T as indicated in FIG. 6, or it may extend over the top 106_T, similarly to the first liner insulating portions 116_IP. A combination of the first liner 116 and the second liner 118 provides a shield liner 119 in the trenches 106. Additional implementation details and/or options, for example for the second liner 118, also may be found in co-owned U.S. Pat. No. 10,720,499, entitled “Semiconductor Device Having Polysilicon Field Plate for Power MOSFETs”, issued Jul. 21, 2020, and hereby fully incorporated herein by reference.

The trench shield 120 is formed (FIG. 16, 1610) in the trenches 106 on the shield liner 119, extending to proximate to the top 106_T. The trench shield 120 may be referred to for clarity as a polysilicon element at the illustrated stage of manufacturing. The trench shield 120 is electrically conductive, and is electrically isolated from the semiconductor material of the substrate 102 by the shield liner 119. The trench shield 120 may be formed by thermal or plasma decomposition of silane or disilane, so that the trench shield 120 may include primarily polycrystalline silicon. By way of one example, the trench shield 120 may be formed of undoped polycrystalline silicon at 600° C. to 620° C., and subsequently implanted with dopants and annealed to provide a desired electrical resistivity. By way of another example, the trench shield 120 may be formed of doped polycrystalline silicon at 500° C. to 580° C. by including dopant reagents with the silane or disilane. Lastly, FIG. 6 illustrates a field oxide 105 by way of a dashed line, with the dashing to indicate that the layer to form the field oxide 105 is formed only in selected locations of the trench-shielded FET 100, as shown in FIG. 1. Accordingly, for those areas where the field oxide 105 is so formed, then subsequent steps would include that layer and structures may be formed relative to it.

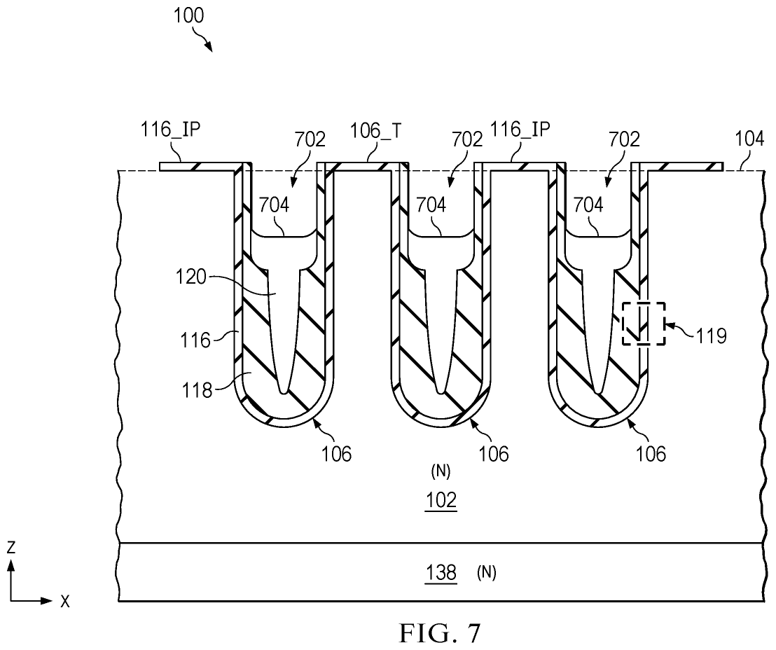

FIG. 7 illustrates the FIG. 6 cross-section after additional fabrication steps, and it also may apply to any one or more of the structures shown above in FIGS. 2 and 4, while the area illustrated by FIG. 3A is covered by the field oxide 105, which essentially forms a mask so as to prevent structure from being formed by the FIG. 7 illustrated steps. Accordingly, unless stated otherwise, in FIG. 7 and later drawings, the illustrated structure are formed in the active area, that is, where the field oxide 105 is not present. In FIG. 7, a mask is formed and patterned over the FIG. 6 structure, after which a desired and selected portion of the FIG. 6 trench shield 120 is removed where exposed (not masked) (FIG. 16, 1612). The portion of the trench shield 120 may be removed by a reactive ion etch (RIE) process, using chlorine or bromine A desired portion of the trench shield 120 may be removed by a timed etch process. The etch leaves a remaining respective portion of the trench shield 120 extending upward from a bottom portion of each the trenches 106, but within each trench 106 leaving a void 702 above each trench shield 120. The process of removing the portion of the trench shield 120 may create a curved (e.g., concave) surface 704 extending atop each trench shield 120.

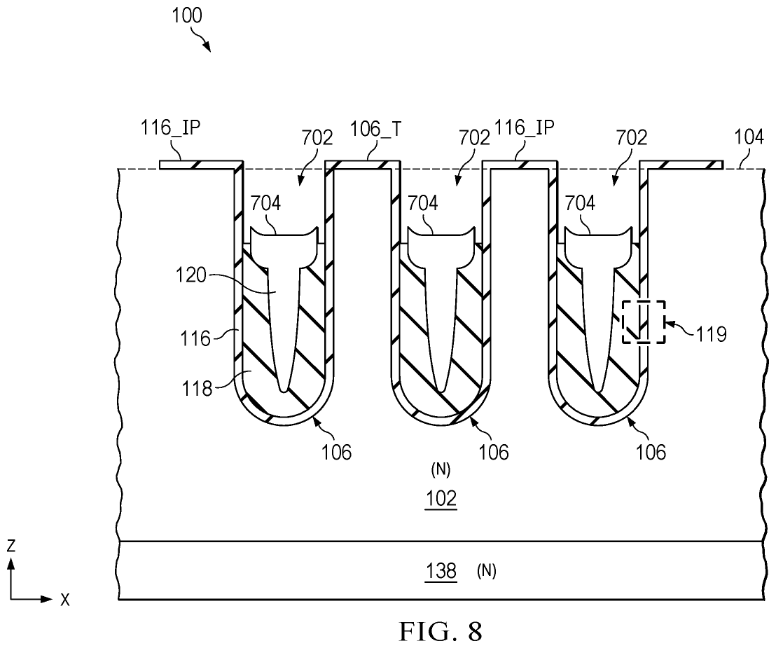

FIG. 8 illustrates the FIG. 7 cross-section after additional fabrication steps. In FIG. 8, an upper portion of the second liner 118 is removed (FIG. 16, 1614) in each of the voids 702, so that the first liner 116 is exposed within the voids 702 and above an upper surface of the remaining portions of the second liner 118. Additional steps may be taken with respect to filling portions of exposed surfaces, as further described in co-owned U.S. Pat. No. 11,302,568, entitled “Trench Shield Isolation Layer”, issued Apr. 12, 2022, and hereby fully incorporated herein by reference.

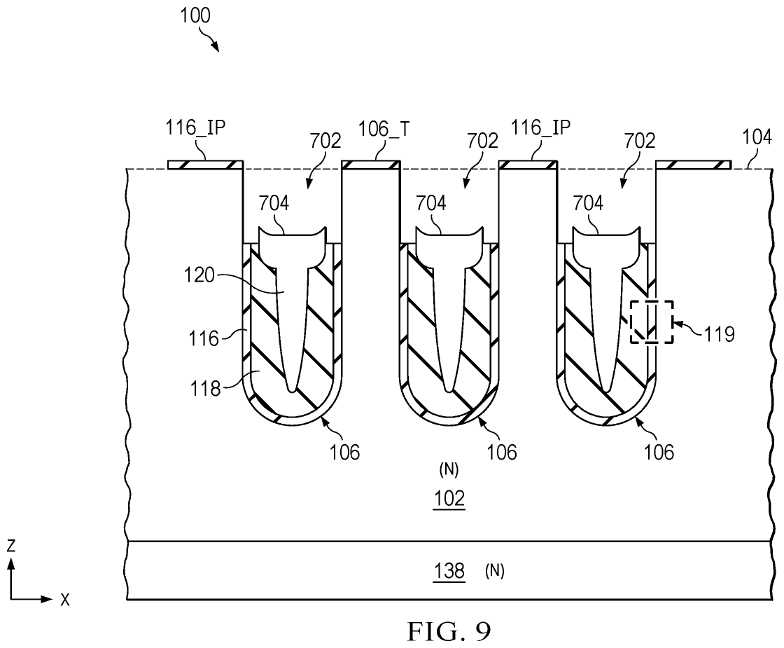

FIG. 9 illustrates the FIG. 8 cross-section after additional fabrication steps. In FIG. 9, a portion of the first liner 116 is removed along the upper portions of the walls of the trenches 106, thereby exposing a corresponding portion of the trench wall (FIG. 16, 1616). For example, the amount of removed upper portion of the first liner 116 may align (in the x-dimension) with the top of the second liner 118 that remains in each of the trenches 106. Removal of this portion of the first liner 116 may be by an aqueous solution of buffered hydrofluoric acid. The top surface 102 of the substrate 104 may remain covered by the first liner insulating portions 116_IP after portions of the first liner 116 are removed in the trenches 106, as depicted in FIG. 9. Alternatively, partial removal of the first liner 116 in the trenches 106 may result in removal of the first liner insulating portions 116_IP where exposed. Forming the first liner 116 thinner than the second liner 118 may advantageously enable removal of portions of the first liner 116 without significant degradation of the second liner 118.

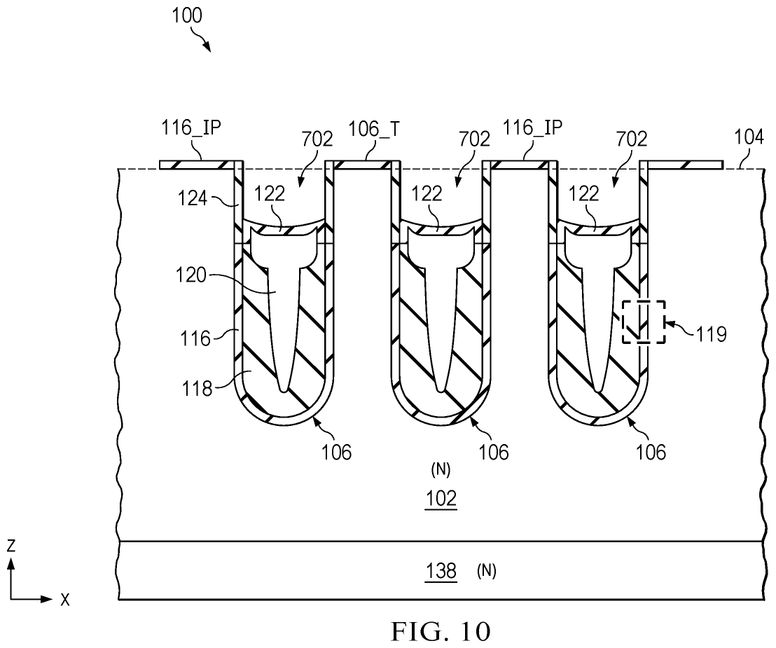

FIG. 10 illustrates the FIG. 9 cross-section after additional fabrication steps (FIG. 16, 1618). In FIG. 10, the lateral insulator 122 and the gate dielectric 124 are formed within each of the FIG. 9 voids 702. In an example, first the lateral insulator 122 may be formed by a thermal oxidation process, for example at a thickness in a range from 100 nm to 400 nm. Second, the gate dielectric 124 is formed along exposed (upper) portions of the wall of the trench 106. The gate dielectric 124 also may be formed by a thermal oxidation process, and it may have a thickness of 5 nm to 500 nm. Other methods for forming the lateral insulator 122 and the gate dielectric 124 are within the scope of this example, while still others may be found in may be found in the above-referenced and incorporated U.S. Pat. No. 11,302,568.

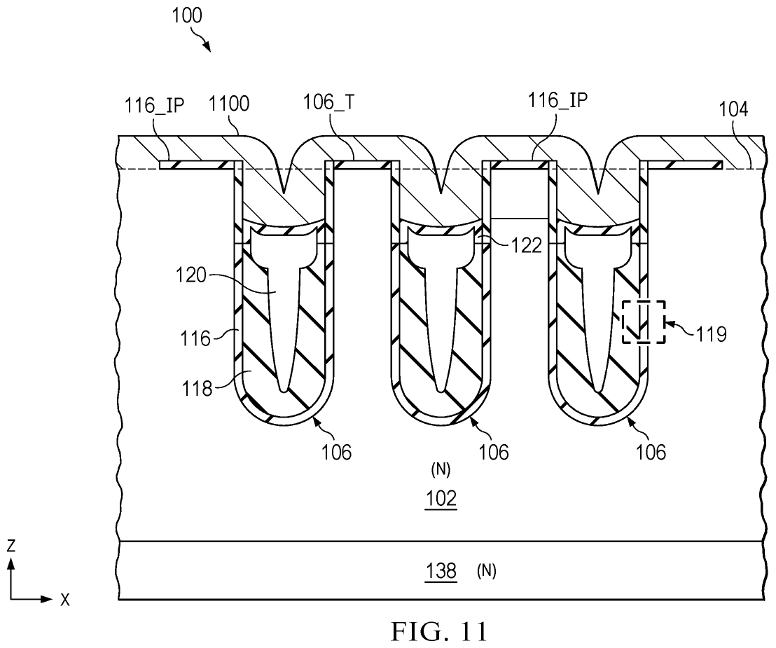

FIG. 11 illustrates the FIG. 10 cross-section after additional fabrication steps. In FIG. 11, a conformal polysilicon layer 1100 is applied atop the trench-shielded FET 100 (FIG. 16, 1620), and thereby fills any exposed voids, including the FIG. 10 voids 702. The conformal polysilicon layer 1100 may include polycrystalline silicon, for example, with appropriate dopants to attain a desired threshold potential during operation of the trench-shielded FET 100.

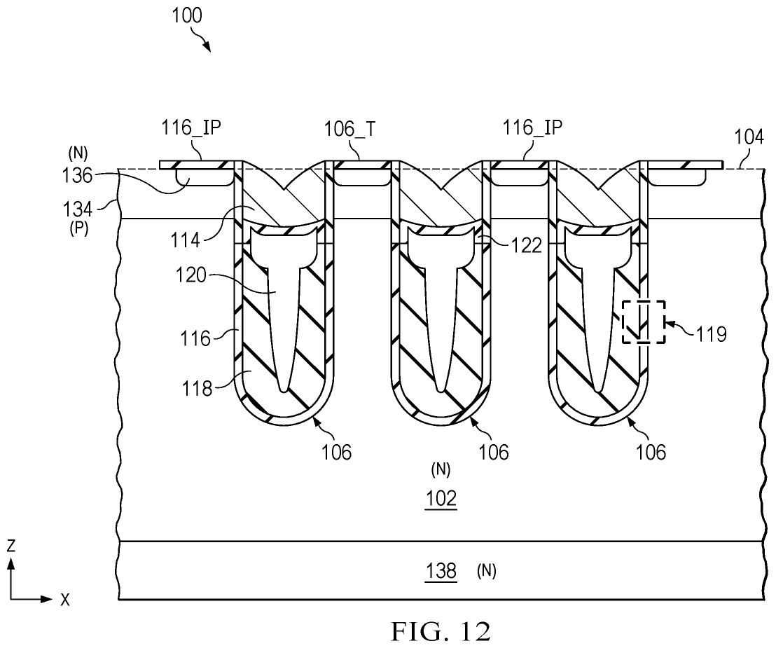

FIG. 12 illustrates the FIG. 11 cross-section after additional fabrication steps. In FIG. 12, the FIG. 11 conformal polysilicon layer 1100 is planarized, for example in the z-dimension (e.g., down) to the upper surface of the first liner insulating portions 116_IP (FIG. 16, 1622). For example, the planarization may be achieved using planar plasma etching, using various different chemistries and processes. The polysilicon planarization leaves remaining portions of the conformal polysilicon layer 1100 in each of the FIG. 9 voids 702, with each of those portions forming a respective gate conductor 114, as introduced in FIG. 2. Accordingly, in the illustrated example, the gate conductors 114 are formed in the active area directly from a planarization of the conformal polysilicon layer 1100 and in a patternless fashion, that is, without an immediately-preceding gate masking step, which otherwise may be required in the formation of gate conductors in various prior transistor structures. Elimination of a separate masking step, as illustrated, is beneficial, for example, in reducing process complexity and cost. Additionally, the source regions 136 (e.g., n-type) are also formed, for example by a relatively high concentration dopant implant (and an optional anneal), to align along the outer upper edges of the trenches 106 and below the first liner insulating portions 116_IP. Note that the source regions 136 are formed within the body layer 134, but FIG. 12 does not expressly illustrate the body layer 134, as it is shown earlier in FIGS. 2 and 4, and it may be formed, for example, using the same mask as used to form the field oxide 105.

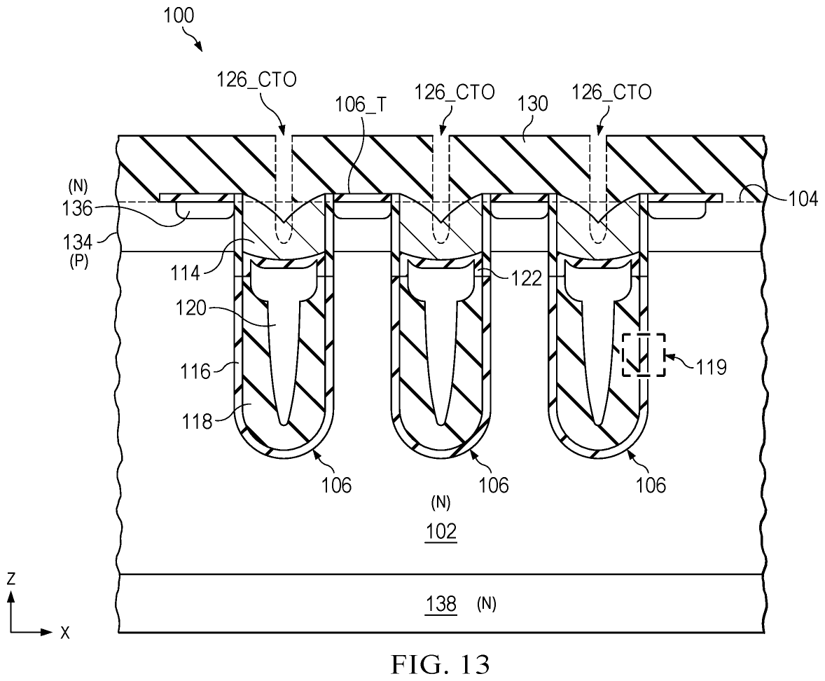

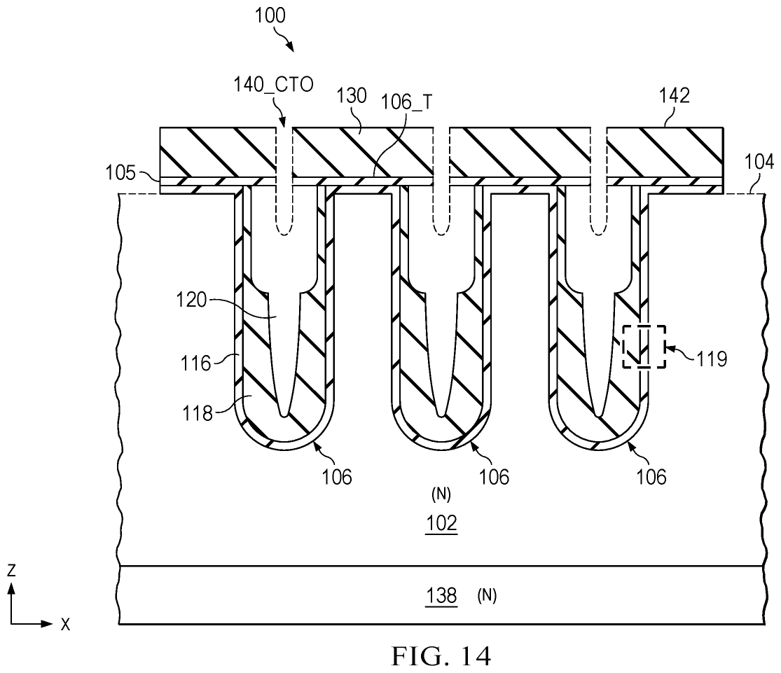

FIG. 13 illustrates the FIG. 12 cross-section after additional fabrication steps, and it also may apply to any one or more of the structures shown above in FIG. 2. Following the FIG. 12 steps, one or more pre-metal dielectric layers are formed (FIG. 16, 1624), which ultimately provide the PMD layer 130, shown again in FIG. 13 as corresponding to FIG. 2 and shown again in FIG. 14 as corresponding to FIG. 3A. For example, a first PMD sublayer 130′ may be formed, in a range of 150 to 250 nm thick, which may be deposited and then densified. Also, for example, after forming the first PMD sublayer, a second PMD sublayer 130″ layer may be formed, for example by a thermal chemical vapor deposition (CVD) process using TEOS, in a range of 800 nm to 900 nm thick. The second PMD sublayer 130″ may be planarized, for example using chemical-mechanical polishing (CMP) or other techniques. Still further, a third PMD sublayer 130′″ may be formed above the planarized second PMD layer, for example with a cap TEOS layer, in a range of 100 nm to 200 nm thick.

After the PMD layer 130 is complete, contact openings 126_CTO are patterned and formed (FIG. 16, 1626), as shown in FIG. 13 by dashed contact lines through the PMD layer. In FIG. 13, the contact openings 126_CTO correspond to where the eventual FIG. 2 gate contacts 126 will be subsequently formed, extending to, or partially into, respective tops of each gate conductor 114. The contact openings 126_CTO may be formed, for example, by any one or more of depositing an anti-reflective coating, depositing and patterning a (e.g., photoresist) mask, and etching according to the mask (e.g., in unmasked areas) to form the illustrated contact openings 126_CTO. Once the contact openings 126_CTO are formed, additional steps are taken to complete the contact (FIG. 16, 1628). These steps may include, as examples, a contact implant, a rapid thermal anneal, a surface clean, plug formation (e.g., tungsten chemical vapor deposition at 300 nm to 500 nm to fill each opening 126_CTO and form the respective contacts 126), CMP of the plugs, and deposition of a metal layer that forms the gate interconnection bus 132 in FIG. 2 (but not re-shown in FIG. 13). The gate interconnection bus 132 may include multiple steps or sub-layers/portions, such as a first deposition of a thinner metal (e.g., titanium at 50 nm), followed by a second deposition of a thicker metal (e.g., aluminum at 500 nm to 3 μm).

FIG. 14 illustrates the FIG. 6 cross-section after additional fabrication steps and toward the completion of the structures shown above in FIG. 3A. Following the FIG. 6 steps, the one or more pre-metal dielectric layers described with respect to FIG. 13, or shown as FIG. 16 step 1624, are also formed over the FIG. 6 structure, so those form over the field oxide 105. Accordingly, when those pre-metal dielectric layers are initially formed, the total thickness of those adds to the thickness of the field oxide 105, so that collectively the device is taller in the z-dimension, for example as compared to when those layers are added in FIG. 13. However, recall that as part of the pre-metal dielectric formation, it includes a planarization, for example using CMP of a second of three different pre-metal dielectric layers. Accordingly, this CMP will remove a greater amount of the pre-metal dielectric material in the area of FIG. 13, as compared to FIG. 14, and upon completion of the CMP, the remaining dielectric structures above the first surface 104 will have the same total thickness in both FIGS. 13 and 14. After the PMD 130 layer is complete, contact openings 140_CTO are patterned and formed, as shown in FIG. 14 by dashed contact lines through the PMD layer 130 (and in FIG. 16, step 1626). In FIG. 14, the contact openings 140_CTO correspond to where the eventual FIG. 3A trench shield contacts 140 will be subsequently formed, extending to, or partially into, respective tops of each trench shield 120. The contact openings 140_CTO may be formed with a same or comparable process to that described for the FIG. 13 contact openings 126_CTO. Once the FIG. 14 contact openings 140_CTO are formed, additional steps are taken to complete the contact. These steps may include, as examples, a contact implant, a rapid thermal anneal, a surface clean, plug formation that fills each opening 140_CTO and forms the respective contacts 140 (and in FIG. 16, step 1628), and deposition of a metal layer as shown by the source/shield interconnection bus 143 in FIG. 3A (but not re-shown in FIG. 14). Like the FIG. 2 gate interconnection bus 132, the FIG. 3A source/shield interconnection bus 143 may include multiple steps or sub-layers/portions, such as a first deposition of a thinner metal (e.g., titanium at 50 nm), followed by a second deposition of a thicker metal (e.g., tungsten at 500 nm). Further, the source/shield interconnection bus 143 may be planarized. Lastly, a metal sputter can be formed atop the source/shield interconnection bus 143.

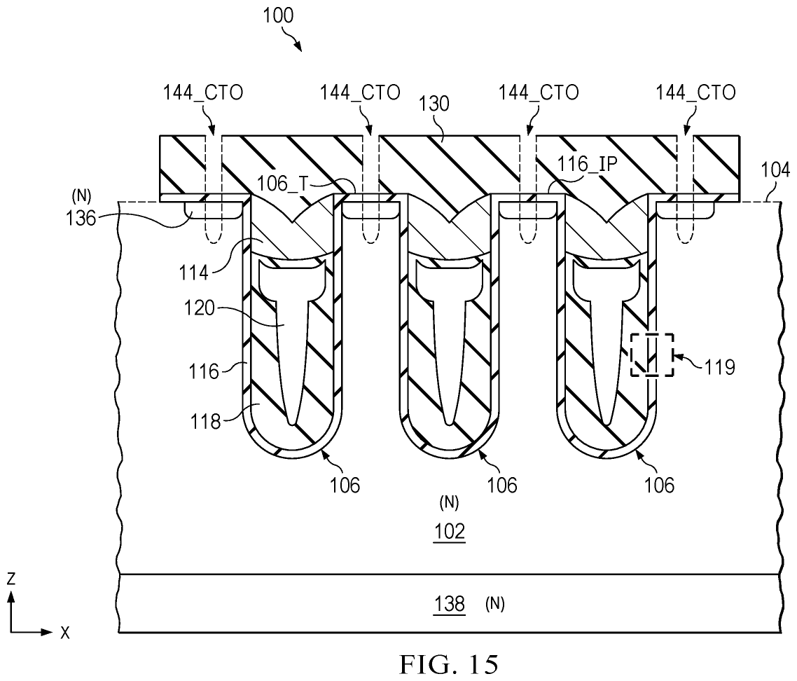

FIG. 15 illustrates the FIG. 12 cross-section after additional fabrication steps, but in a different location along the FIG. 1 y-dimension, to demonstrate the completion of the structures shown above in FIG. 4. Specifically, at the same time that the FIGS. 13 and 14 PMD layer 130 is formed, it also may be formed in the FIG. 15 depicted area (and as part of FIG. 16, step 1624). Accordingly, the PMD layer 130 forms over the gate conductors 114 as well as the first liner insulating portions 116_IP. Additionally, for example, at the same time that the FIG. 14 contact openings 140_CTO are formed, that same process may form the FIG. 15 contact openings 144_CTO (and as part of FIG. 16, step 1626). Still further, plugs followed by a metal layer may be subsequently formed to fill both sets of contact openings and apply metal over the plugs (FIG. 16, step 1628), such as the FIGS. 3 and 4 source/shield interconnection bus 143, so that sets of both trench shield contact 140 contacts and source contacts 144 are concurrently formed in the respective contact openings, and so that they are electrically connected by a mutual same metal layer, which later can be connected to a same electrical potential. Further, given that a same metalization is common to various different sets of contacts, the top of that layer may be planarized with a single CMP step, rather than potentially requiring a chemical planarization etch.

Given the preceding and FIGS. 13 through 15, note that the contact opening etch, to the extent applied to multiple different types of contacts (e.g., source contact 144, gate contact 126, trench shield contact 140), can be from a same common layer. Further, the common layer may present a common upper plane, so that each contact opening starts from that common plane, and may have a common depth. For example, in FIGS. 13 through 15, each contact opening extends downward from the planar top of the PMD layer 130 and extends to approximate a same depth, meaning within a range of 0.3 μm to 0.8 μm below the top surface of the PMD layer 130, to provide contact to each of the corresponding structures shown in FIGS. 13 through 15 (e.g., source region 136, gate conductor 114, trench shield 120). Further in FIGS. 13 through 15, the contact plug formation (with CVDW) can be a same step, as can be the subsequent metal layer (e.g., aluminum), with proper positioned metal pattern and etching. Accordingly, various of the contact process parameters can be the same, thereby resulting in a relatively uniform formation quality of the contacts and a resulting uniform performance from each. Additionally, the CMP to planarize the dielectric then allows the metal above the dielectric also to be planarized using CMP, which gives a better overall process control and uniformity. Still further, the results may be compared to a non-planar topography in which contacts are formed from different elevations, in which case the characteristics of the contacts may vary, resulting in nonuniform electrical performance, e.g. resistance. For example, as shown in FIGS. 13 through 15, because each contact opening has (or approximately) a same depth downward from the upper surface of the PMD layer 130, the DOF of a photolithographic process to form each opening may be larger than for a nonplanar top surface of the PMD layer 130, thereby providing a same or relatively uniform quality of structure for each contact hole in which a contact will be formed, and with relatively uniform exposure energy levels imparted to a photoresist layer used in the formation of each contact opening. Further, improving uniformity of contact opening structure likewise improves the contact formed within each opening, which likewise improves overall wafer-level reliability and transistor performance, for example as relating to increased voltage breakdown and reduced transistor drain-to-source on-resistance.

From the above, one skilled in the art should appreciate that examples are provided for semiconductor fabrication and devices, for example with respect to trench-shielded FETs. Such examples may improve both structure and formation methods. For example, trench gates can be formed without an additional patterning step for such formation. As another example, FET contacts, for example to any one or more of gate conductors, source regions, and trench shields, may be formed using mutual processes and from a mutual plane, including the step of a favorable CMP planarization. As another example, individual device performance is more consistent, and wafer reliability and yield may be improved. Still further, other benefits are the flexibility of variations for different examples, in that, for example, certain benefits may be achieved from differing processes or implementing only portions, or adding additional steps/structures, compared to the entire example shown in the provided figures. As a final example, additional modifications are possible in the described embodiments, and other embodiments are possible, within the scope of the following claims.

What is claimed is:

1. An integrated circuit, comprising:
first and second trenches in a semiconductor substrate;
a semiconductor mesa between the first and second trenches;
a source region having a first conductivity type and a body region having an opposite second conductivity type within the semiconductor mesa,
a trench shield within the first trench;
a gate electrode over the trench shield between first and second sidewalls of the first trench;
a gate dielectric on a sidewall of the first trench between the gate electrode and the body region;
a pre-metal dielectric (PMD) layer over the gate electrode;
a gate contact through the PMD layer that touches the gate electrode between the first and second sidewalls; and
a trench shield contact through the PMD layer that touches the trench shield between the first and second sidewalls.

2. The integrated circuit of claim 1 wherein the gate contact and the trench shield contact have a same depth below a top surface of the semiconductor substrate.

3. The integrated circuit of claim 1 further including a source contact electrically contacting the source region, the source contact and the gate contact having a same depth below a top surface of the semiconductor substrate.

4. The integrated circuit of claim 1 further comprising a source contact ohmically contacting the source region, wherein tops of the gate contact, the trench shield contact and the source contact are coplanar.

5. The integrated circuit of claim 1 wherein the PMD layer comprises a planarized dielectric layer.

6. The integrated circuit of claim 5 and further including interconnections in a metal layer over the planarized dielectric layer, the interconnections having top surfaces that are coplanar.

7. The integrated circuit of claim 1 and further including:
a first trench shield contact electrically contacting the trench shield between the first and second sidewalls.

8. The integrated circuit of claim 7 wherein the trench shield has a first portion with a top surface at a first depth below a top surface of the semiconductor substrate, and has a second portion having a top surface at a second depth below the top surface, wherein the first depth is greater than the second depth and the trench shield contact touches the trench shield along the second portion of the trench shield.

9. The integrated circuit of claim 1 wherein the gate contact and the trench shield contact have a same depth below a surface of a pre-metal dielectric (PMD) layer over the semiconductor substrate.

10. A semiconductor device, comprising:
a trench located in a semiconductor layer;
a polysilicon gate electrode within the trench and having a first portion in contact with a pre-metal dielectric (PMD) layer;
a polysilicon shield within the trench and having a first portion in contact with the PMD layer and a second section spaced apart from the PMD layer by the gate electrode;
a gate contact extending from a top surface of the PMD layer to the gate electrode; and
a trench shield contact extending from the top surface of the PMD layer to the first portion of the polysilicon shield.

11. The semiconductor device of claim 10 wherein a top surface of the gate contact is coplanar with a top surface of the shield contact.

12. The semiconductor device of claim 10 wherein the gate contact is electrically connected to a first metal layer over the PMD layer, and the shield contact is electrically connected to a different second metal layer over the PMD layer, the first metal layer being coplanar with the second metal layer.

13. The semiconductor device of claim 10 further comprising a source contact extending from the top surface of the PMD layer to the semiconductor layer adjacent the trench, wherein a top surface of the source contact is coplanar with top surfaces of the gate contact and the shield contact.

14. A method of forming an integrated circuit, comprising:
forming a trench in a semiconductor substrate, the trench having first and second trench sidewalls;
forming a first dielectric layer along the first and second trench sidewalls;
forming a polysilicon element between the first and second trench sidewalls, the polysilicon element spaced apart from the first trench sidewall and the second trench sidewall by the first dielectric layer;
partially removing the polysilicon element along a portion of the trench thereby forming a trench shield;
forming a gate conductor within the trench portion and spaced apart from the trench shield by a lateral insulator; and
forming a trench shield contact that lands on the trench shield and a gate contact that lands on the gate conductor, the trench shield contact and gate contact extending through a pre-metal dielectric (PMD) layer over the trench.

15. The method of claim 14 and further including forming a source region in the semiconductor substrate and adjacent the trench.

16. The method of claim 14 further comprising planarizing the PMD layer before forming the shield contact and the gate contact.

17. The method of claim 14 wherein the shield contact and the gate contact extend a same distance between a top surface of the PMD layer and a bottom of the trench.

18. The method of claim 14 and further including:
forming a source region in the semiconductor substrate and adjacent the trench; and
forming source contact that lands in the source region and extends through the PMD layer,
wherein top surfaces of the gate contact, the shield contact and the source contact are coplanar.

19. The method of claim 18, wherein the gate contact, the shield contact and the source contact are formed concurrently.
